(19) United States
(12) Patent Application Publication
(10) Pub. No.: US 2010/0029084 A1
(43) Pub. Date: Feb. 4, 2010

(54) PATTERN FORMING METHOD AND PATTERN FORMING DEVICE

(76) Inventors: Takeshi KOSHIBA, Yokohama-Shi (JP); Yuji KOBAYASHI, Yokkaichi-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/510,863

(22) Filed: Jul. 28, 2009

(30) Foreign Application Priority Data
Jul. 29, 2008 (JP) 2008-194884

(51) Int. Cl. H01L 21/311; H01L 21/306

(52) U.S. Cl. 438/701; 156/345.24; 257/E21.219

(57) ABSTRACT

A pattern size is arbitrarily adjusted with the use of the same template in imprint lithography. A pattern forming method includes: applying droplets onto a substrate; forming a light curing organic film by bringing a template into contact with the droplets, the template having a pattern formed with protrusions and grooves; adjusting and keeping the distance between the template and the substrate at a predetermined value; forming a cured organic film including organic film convex portions and organic film concave portions each having a predetermined film thickness by curing the light curing organic film through exposure to ultraviolet light, the organic film convex portions and the organic film concave portions corresponding to the grooves and protrusions of the template; detaching the template from the cured organic film; and forming a resist pattern by performing etching to turn each of the organic film concave portions into a tapered shape under such conditions as to obtain a predetermined taper angle, the resist pattern having openings each having a smaller width than the protrusions of the template.

### CROSS-REFERENCE TO RELATED APPLICATION

This application is based upon and claims the benefit of priority from prior Japanese Patent Application No. 2008-194884, filed on Jul. 29, 2008, the entire contents of which are incorporated herein by reference.

### BACKGROUND OF THE INVENTION

1. Field of the Invention

The present invention relates to a pattern forming method and a pattern forming device, and more particularly, to a pattern forming method and a pattern forming device that utilize imprint lithography.

2. Background Art

While semiconductor devices are becoming smaller and smaller, the difficulty is increasing in fine processing by conventional photolithography, and there is a demand for techniques to replace the conventional fine processing. As one of the techniques, attention is being drawn to imprint lithography.

In the imprint lithography, an optical imprint technique is most expected to be applied to semiconductor lithography. By this technique, an original plate (hereinafter referred to as the template) having a reverse pattern that is equivalent to a mirror image of the pattern to be transferred is prepared in advance. This template is brought into contact with a light curing organic material layer applied onto a substrate or a film to be processed. The organic material layer is then exposed to ultraviolet light, and is cured. In this manner, the desired pattern is transferred onto the organic material layer (see Japanese Patent Application Laid-Open No. 2000-194142, for example).

### SUMMARY OF THE INVENTION

According to one embodiment of the present invention, there is provided a pattern forming method for transferring pattern formed on a template onto an organic material layer. This pattern forming method includes: applying an organic material onto a substrate to be processed; bringing the template having a pattern into contact with the organic material, and maintaining a template distance at a predetermined value, the pattern being formed with protrusions and grooves, the template distance being the distance between the template and the substrate to be processed; forming a cured organic film by curing the organic material, the cured organic film being formed with organic film convex portions and organic film concave portions each having a predetermined film thickness, the organic film convex portions and the organic film concave portions corresponding to the grooves and the protrusions, respectively; detaching the template from the cured organic film; and forming a resist pattern having openings by performing etching on the organic film concave portions in such a manner as to obtain a predetermined taper angle, each of the organic film concave portions being formed into a tapered shape or a reverse tapered shape, each of the openings having a smaller or greater width than the protrusions and being adjusted to a desired pattern size.

According to another embodiment of the present invention, there is provided a pattern forming device that includes: a design condition input unit that has design conditions input thereinto; a residual film thickness calculating unit that calculates a target value of a residual film thickness, using the design conditions input into the design condition input unit; a processing condition generating unit that generates a template distance between a template and a substrate to be processed, and/or a drop recipe defining conditions for applying an organic material onto the substrate to be processed, based on the target value of the residual film thickness; an alignment control unit that controls a distance between the template and the substrate to be processed, in accordance with the template distance generated by the processing condition generating unit; and an application amount control unit that controls a discharging unit that discharges the organic material onto the substrate to be processed, in accordance with an amount of the organic material defined by the processing condition generating unit.

### BRIEF DESCRIPTION OF THE DRAWINGS

FIG. 1 is a plan view of a semiconductor wafer that has droplets dispersed onto an area equivalent to one shot;

FIG. 2A is a cross-sectional view illustrating a procedure in a pattern forming method in accordance with a first embodiment;

FIG. 2B is a cross-sectional view illustrating the procedure following the procedure shown in FIG. 2A in the pattern forming method in accordance with the first embodiment;

FIG. 2C is a cross-sectional view illustrating the procedure following the procedure shown in FIG. 2B in the pattern forming method in accordance with the first embodiment;

FIG. 2D is a cross-sectional view illustrating the procedure following the procedure shown in FIG. 2C in the pattern forming method in accordance with the first embodiment;

FIG. 2E is a cross-sectional view illustrating the procedure following the procedure shown in FIG. 2D in the pattern forming method in accordance with the first embodiment;

FIG. 2F is a cross-sectional view illustrating the procedure following the procedure shown in FIG. 2E in the pattern forming method in accordance with the first embodiment;

FIG. 3A is a cross-sectional view of the cured organic film and the substrate, with an organic film concave portion being the center, in a case where each organic film concave portion is processed into a tapered shape;

FIG. 3B is a cross-sectional view of the cured organic film and the substrate, with an organic film concave portion being the center, in a case where each organic film concave portion is processed into a reverse tapered shape;

FIG. 4 shows the relationship between the film thickness of each organic film concave portion and the reduction in the width of each opening;

FIG. 5 is a functional block diagram of a pattern forming device in accordance with a second embodiment; and

FIG. 6 is a flowchart illustrating the method for adjusting the pattern size.

### DESCRIPTION OF THE EMBODIMENTS

Before the embodiments of the present invention are described, how the inventors developed the present invention is explained. Imprint lithography greatly differs from conventional photolithography in that the pattern size to be transferred onto a semiconductor wafer is uniquely determined by the pattern size formed on the template, and cannot be adjusted during the wafer processing. In the conventional photolithography, on the other hand, the pattern size can be arbitrarily adjusted during the wafer processing by changing the exposure conditions or the like, even if the same photomask is used.

In the imprint lithography, however, such adjustment cannot be performed. Therefore, it is necessary to reform the template, in a case where the pattern size is to be adjusted by feeding back the results of measurement carried out on the design characteristics of the film to be processed or the characteristics of a produced device. This results in an increase in Turn-Around Time (TAT). More specifically, the period of time required for developing a product that does not have a clear target value for the pattern size might be prolonged, or the period of time required for solving soluble problems caused at the time of mass production might be made longer due to the adjustment of the pattern size.

The present invention has been made in view of the above circumstances, and aims to provide a function to arbitrarily adjust the pattern size with the use of the same template as in the photolithography, and minimize the increase in TAT.

More specifically, the thickness of each concave portion of an organic film (a resist pattern) having a concavity and convexity pattern formed by an imprint technique is adjusted to a value based on a desired pattern size. Etching is then performed on the organic film concave portions under such conditions as to cause a design transform difference, so that each of the organic film concave portions is formed into a tapered shape or a reverse tapered shape. In this manner, the width of each of the openings or the pattern size is adjusted.

The following is a description of the embodiments of the present invention, with reference to the accompanying drawings. In the drawings, like components are denoted by like reference numerals, and explanation of those components will not be repeated.

A first embodiment concerns a pattern forming method for adjusting a pattern size by performing processing on the organic film concave portions under such conditions as to cause a design transform difference. A second embodiment concerns a pattern forming device that forms a pattern of a desired size with the use of the same template.

### First Embodiment

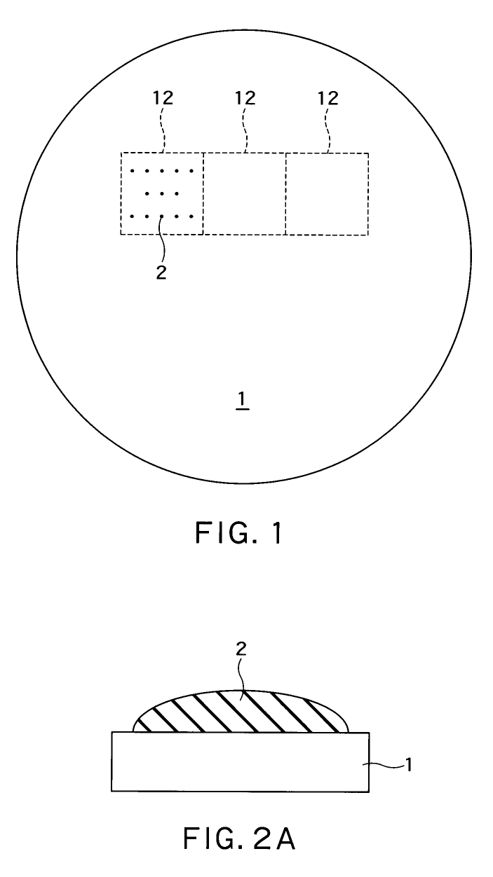

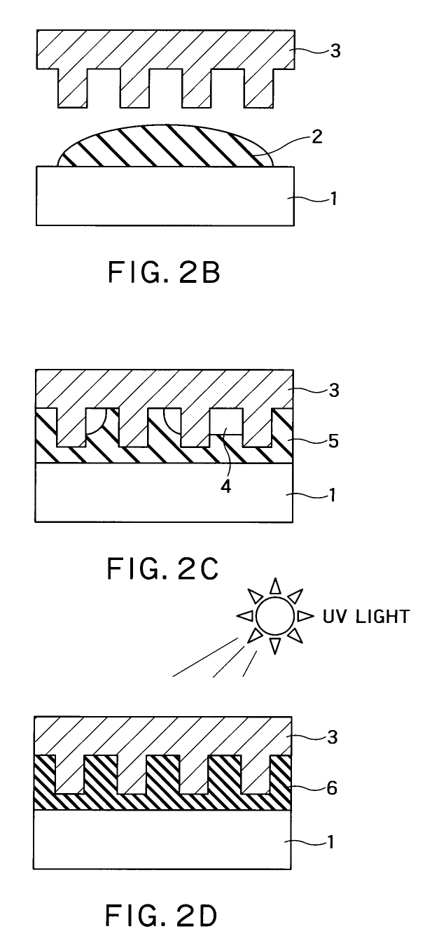

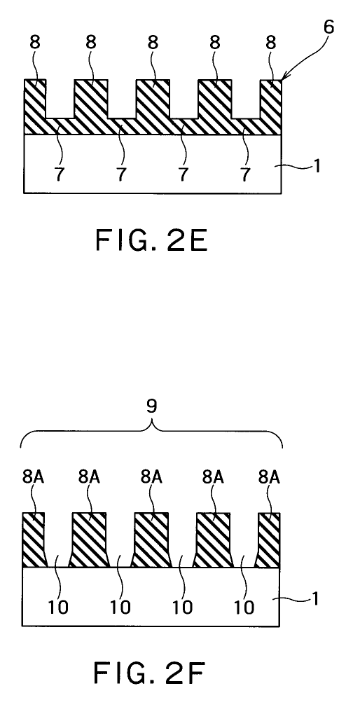

Referring now to FIG. 1 and FIGS. 2A through 2F, a pattern forming method in accordance with the first embodiment of the present invention is described. FIG. 1 is a plan view of a semiconductor wafer (a substrate). FIGS. 2A through 2F are cross-sectional views illustrating the procedures of the pattern forming method in accordance with this embodiment.

1) First, as shown in FIG. 1, a light curing organic material (a resist material) is applied onto a region 12 of one shot on a substrate 1. The application of the organic material is performed by dispersing droplets 2 of a light curing organic material. FIG. 2A is an enlarged view of one of the dispersed droplets 2. The amount of the organic material to be dispersed is controlled based on a desired film thickness of each organic film concave portion 7 (described later). More specifically, the amount of organic material to be dispersed is controlled by changing the distribution form of the droplets 2, the distribution density, or the size (the volume) of each droplet 2.

The amount of the organic material to be applied is also adjusted to a sufficient amount to fill the space between the substrate 1 and a template 3 (described later) and the pattern grooves of the template 3, depending on the set value (the predetermined value) of the distance between the substrate 1 and the template 3.

Alternatively, a film to be processed may be formed on the substrate 1 in advance, and the organic material may be applied onto the film to be processed.

2) As shown in FIG. 2B, the template 3 having the pattern of one shot formed therein is brought closer to the substrate 1 and into contact with the droplets 2. As a result, the droplets 2 are combined to form a light curing organic film 5, as shown in FIG. 2C.

The template 3 is made of quartz that has high transmissivity with respect to ultraviolet rays, for example, and can transmit light that cures the light curing organic material. A reverse pattern equivalent to a mirror image of a desired semiconductor pattern is formed on the surface of the template 3.

3) The template 3 is brought even closer to the substrate 1, and the distance between the substrate 1 and the template 3 (hereinafter referred to as the template distance) is maintained at a predetermined value. The template distance is controlled to be equal to the set value (the predetermined value) based on the desired film thickness of the concave organic film 7.

The control of the template distance of the nanometer order is performed by measuring the distance between the template 3 and the substrate 1 with a laser interferometer or the like, and/or measuring the suppress strength of the template 3 with a piezoactuator.

4) The template distance is maintained at the predetermined value for a spread time. During the spread time, the organic material of the light curing organic film 5 fills the grooves of the minute pattern formed in the template 3 by virtue of a capillary vessel phenomenon. At first, the organic material does not sufficiently fill the grooves in the template 3, and filling defects 4 are formed at corners of the pattern in the template 3, as shown in FIG. 2C. After the spread time has passed, the organic material spreads into every tough corner of the pattern grooves, and the filling defects 4 disappear.

5) Light (ultraviolet rays, for example) is then emitted onto the light curing organic film 5, as shown in FIG. 2D. As a result, the light curing organic film 5 is cured, and is turned into a cured organic film 6 that has a concavity and convexity pattern to be engaged with the pattern formed on the template 3.

6) The template 3 is then detached from the cured organic film 6, as shown in FIG. 2E. As can be seen from FIG. 2E, the cured organic film 6 is formed with the organic film concave portions 7 (hereinafter also referred to as the residual films) and organic film convex portions 8. The organic film concave portions 7 each have the desired film thickness, because the template distance is controlled in the above described manner.

7) The substrate 1 is then shifted by the amount of a region 12, and the above described procedures 1) through 6) are carried out. This is repeated until the entire surface of the substrate 1 is scanned.

8) Breakthrough etching is then performed to remove the organic film concave portions 7 to form openings 10. The breakthrough etching is performed where a design transform difference is caused. More specifically, each of the organic film concave portions 7 is processed to have a tapered shape, with the etching being performed so as to obtain a desired taper angle. The etching gas used here is a methane-based gas, for example. With such an etching gas, a reactive product can be readily generated. The etching is performed while the reactive product is deposited on the sidewalls of the holes formed by the etching. Thus, the organic film concave portions 7 are processed to have tapered shapes.

By the breakthrough etching, tapered openings 10 each having the desired taper angle are formed at the positions corresponding to the organic film concave portions 7, as shown in FIG. 2F. The width of each of the openings 10 (the width of each exposed face of the substrate 1) is equal to a desired pattern size.

FIG. 2F is a cross-sectional view illustrating the procedure carried out after the breakthrough etching. As can be seen from FIG. 2F, a resist pattern 9 formed with the non-etched remaining organic film convex portions 8A and the openings 10 on the substrate 1.

9) With the resist pattern 9 serving as a mask, etching is performed on the substrate 1. In this manner, the desired semiconductor pattern is obtained.

As described above, the openings 10 are formed by processing the organic film concave portions 7 each having an adjusted film thickness into tapered shape under such conditions as to obtain a predetermined taper angle. Accordingly, the width of each of the openings 10 can be made smaller than the width of each of the organic film concave portions 7 by a desired amount. On the other hand, if the organic film concave portions 7 are processed to have reverse tapered shapes, the width of each of the openings 10 can be made greater than the width of each of the organic film concave portions 7 by a desired amount.

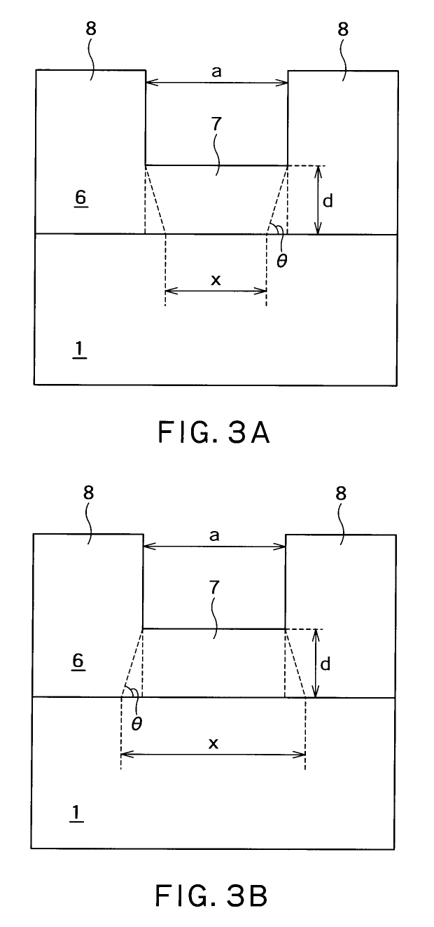

Referring now to FIGS. 3A and 3B, this aspect of the embodiment is described in greater detail. FIGS. 3A and 3B are cross-sectional views of the cured organic film 6 and the substrate 1, with an organic film concave portion 7 being the center. FIG. 3A illustrates a case where the organic film concave portions 7 are formed into tapered shapes. FIG. 3B illustrates a case where the organic film concave portions 7 are formed into reverse tapered shapes.

As can be seen from FIG. 3A, in the case where the organic film concave portions 7 are formed into tapered shapes, the width of each of the openings 10 is expressed by the following equation (1):

x=a−2d·tan(90°−θ) (1)

Here, x represents the width of each of the openings 10 (the pattern size), a represents the width of each of the organic film concave portions 7, d represents the film thickness of each of the organic film concave portions 7 (the residual film thickness), and θ represents the taper angle.

Likewise, as can be seen from FIG. 3B, in the case where the organic film concave portions 7 are formed into reverse tapered shapes, the width of each of the openings 10 is expressed by the following equation (2):

x=a+2d·tan(90°−θ) (2)

As can be seen from the equations (1) and (2), the pattern size x can be adjusted by changing the residual film d, even if the same template is used or the width a of each of the organic film concave portions 7 is fixed.

For example, if the residual film thickness is 15 nm, and the breakthrough etching is performed so that the taper angle becomes 80 degrees, the pattern size becomes smaller than the width of each of the organic film concave portions 7 by 5.3 nm. If the residual film thickness is 30 nm under the same etching conditions (or with the same taper angle), the pattern size becomes smaller by 10.6 nm. In this manner, by adjusting the residual film thickness in the range of 15 nm to 30 nm, the pattern size is adjusted within a 5.3 nm range.

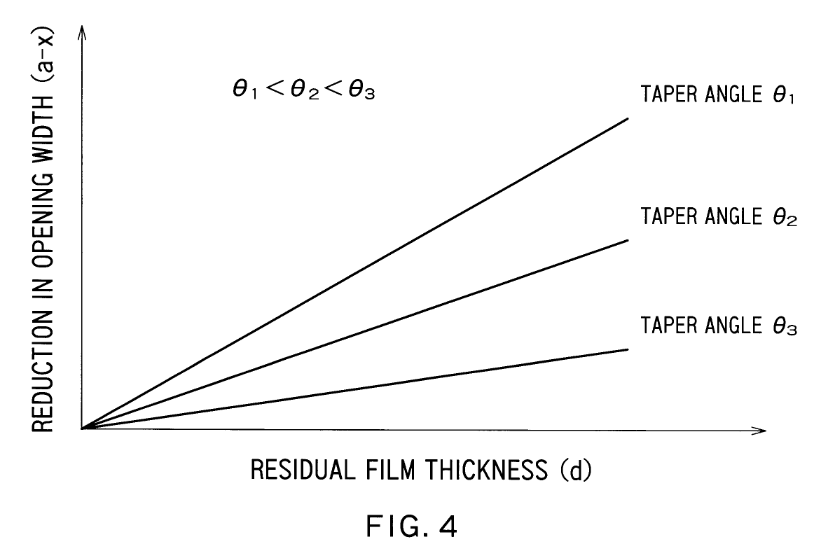

FIG. 4 shows the relationship between the residual film thickness d and the reduction a−x of the width of each of the openings 10, with the taper angle θ being the parameter. As can be seen from FIG. 4, the width of each of the openings or the pattern size can be arbitrarily adjusted within a predetermined range by changing the residual film thickness.

The pattern size may be adjusted by changing the taper angle. The taper angle can be adjusted by changing the conditions for breakthrough etching.

Next, the variable range of the residual film thickness (the film thickness of each of the organic film concave portions 7) is described. The lower limit of the residual film thickness is determined by the specification of the imprint lithography device. On the other hand, the residual film thickness can be made greater, as long as the residual film thickness does not hinder the breakthrough etching. Since the organic film convex portions 8 and the organic film concave portions 7 are made of the same organic material, the amount of each organic film convex portion 8 etched by the breakthrough etching is substantially the same as the amount of each organic film concave portion 7 etched by the breakthrough etching. Accordingly, the difference in film thickness between each organic film convex portion 8 and each organic film concave portion 7 is unvaried before and after the breakthrough etching.

Processing of the film to be processed can be performed by taking advantage of the characteristics. For example, in a case where the film to be processed is a silicon-containing organic film of 45 nm in film thickness, a film thickness of 70 nm is sufficient for the resist pattern 9 at the time of the processing of the silicon-containing organic film. Therefore, the pattern grooves of the template 3 should be formed so that the difference in film thickness between each organic film convex portion 8 and each organic film concave portion 7 is 70 nm. In this manner, the resist pattern 9 of 70 nm in film thickness is maintained, and a silicon-containing organic film of 45 nm in film thickness can be processed, regardless of the film thickness of each of the organic film concave portions 7, after the breakthrough etching.

Although etching is performed only on the cured organic film 6 by performing the breakthrough etching in the above description, the cured organic film 6 and one or more processed films located under the cured organic film 6 may be collectively processed. For example, the cured organic film 6, a silicon-containing organic film formed on the substrate 1, and the substrate 1 may be collectively processed.

Although a light curing organic film is used in the above description, the pattern size can be adjusted in the same manner as in this embodiment by imprint lithography involving a heat curing organic material.

a resist pattern or a semiconductor pattern may be experimentally formed by the above method in advance, and the results of measurement carried out on the various parts of the pattern size may be fed back to the adjustment of the film thickness of each organic film concave portion 7. For example, after the cured organic film 6 is experimentally formed, the film thickness of each of the organic film concave portions 7 may be measured, and the measurement result may be fed back to the adjustment of the film thickness of each of the organic film concave portions 7. Also, the film thickness of each of the organic film concave portions 7 may be adjusted with the use of the results of measurement carried out on the width of each of the openings 10 formed by the breakthrough etching or measurement carried out on the size of the semiconductor pattern (such as the width of each opening in the substrate 1 etched along the mask) formed with the use of the resist pattern 9 as the mask. Based on any combination of the results of the above measurement, the film thickness of each of the organic film concave portions 7 may be adjusted. In other words, the set value (the predetermined value) of the desired film thickness of each of the organic film concave portions 7 may be determined based on any combination of the results of the above measurement.

Next, an example case where a semiconductor memory device pattern is formed by the pattern forming method in accordance with this embodiment is described. A semiconductor memory device is normally formed with a cell region having memory cells integrated therein at high density, and a peripheral region having peripheral circuits such as memory cell drive circuits placed therein at relatively low density. To obtain larger capacity, the cell region is designed according to the minimum design rule, and a miniature pattern is formed in the cell region than in the peripheral region. Therefore, in formation of a pattern for a semiconductor memory device, a template having several regions with different densities is used. With the use of such a template, the film thicknesses of the organic film concave portions 7 might vary between the cell region and the peripheral region, due to the difference in coverage factor (the proportion of the grooves with respect to the region). In such a case, it becomes unclear on which result of film thickness measurement the adjustment of the film thickness of each organic film concave portion 7 should be based.

Attention should be paid to the cell region that has the smallest pattern size set value and is likely to be affected by the pattern size. Therefore, in the formation of the pattern for a semiconductor memory device, the film thickness of each organic film concave portion 7 is adjusted based on the result of the measurement carried out on the cell region. In other words, the set value (the predetermined value) of the desired film thickness of each organic film concave portion 7 may be determined based on the result of measurement carried out on the cell region.

As described above, in accordance with this embodiment, a resist pattern having a residual film of a predetermined film thickness is formed by imprint lithography, and the residual film portions are processed into tapered forms under such etching conditions as to obtain a predetermined taper angle. Even with the same template, the pattern size can be arbitrarily adjusted by changing the film thickness of each residual film portion and/or the taper angle. Also, a desired pattern size can be obtained by feeding back the result of measurement carried out on the formed pattern size in changing the processing conditions. As a result, the TAT increase due to the reform of the template can be minimized.

### Second Embodiment

Next, the second embodiment of the present invention is described. A pattern forming device in accordance with this embodiment uses the same template to obtain a pattern of a desired size.

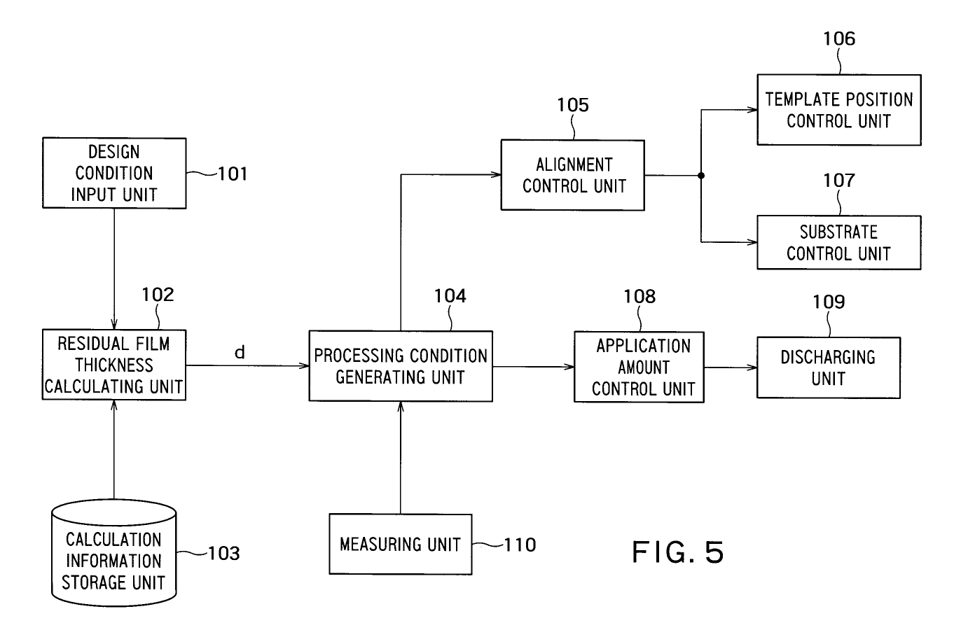

First, the structure of this pattern forming device is described. FIG. 5 is a functional block diagram of the pattern forming device in accordance with the second embodiment of the present invention. As can be seen from FIG. 5, the pattern forming device in accordance with this embodiment includes a design condition input unit 101, a residual film thickness calculating unit 102, a calculation information storage unit 103, a processing condition generating unit 104, an alignment control unit 105, a template position control unit 106, a substrate control unit 107, an application amount control unit 108, a discharging unit 109, and a measuring unit 110.

Next, the above components are described in detail.

Design conditions are input into the design condition input unit 101 by an operator. The design conditions concern a desired pattern size, a taper angle, and the pattern width of the template 3 described in the first embodiment, for example. Instead of the value of the taper angle, the conditions such as the type of etching gas for breakthrough etching may be input. Instead of the value of the pattern size, the amount of adjustment (a decrease or increase in width) to be made on the pattern size may be input.

The residual film thickness calculating unit 102 calculates a target value of the residual film thickness, based on the design conditions that are input to the design condition input unit 101. For example, the target value of the residual film thickness is calculated according to the following equation (3):

e=(b−x)/2 tan(90°−θ) (3)

Here, e represents the target value of the residual film thickness, b represents the pattern width of the template, x represents the desired pattern size, and θ represents the taper angle.

This equation (3) may be stored in the calculation information storage unit 103.

The calculation information storage unit 103 stores the information to be used for calculating the target value e of the residual film thickness from the design conditions input into the design condition input unit 101. For example, the calculation information storage unit 103 may store a database that associates the design conditions for breakthrough etching with taper angles. In such a case, the residual film thickness calculating unit 102 receives the conditions for breakthrough etching from the design condition input unit 101, and obtains a taper angle satisfying the conditions from the calculation information storage unit 103. Based on the value of the obtained taper angle, the residual film thickness calculating unit 102 calculates the target value of the residual film thickness.

Based on the target value of the residual film thickness calculated by the residual film thickness calculating unit 102, the processing condition generating unit 104 generates processing conditions such as a template distance and/or a “drop recipe”. The drop recipe is used to set the amount of application of an organic material to be applied onto a region of one shot on the substrate 1. More specifically, the drop recipe is used to set the distribution form and distribution density of the droplets 2, and the size (the volume) of each droplet 2. Based on the measurement result received from the measuring unit 110 described later, the processing condition generating unit 104 changes the template distance and/or the drop recipe.

The alignment control unit 105 controls the template position control unit 106 and the substrate control unit 107, so as to adjust the template distance to the distance generated by the processing condition generating unit 104.

The template position control unit 106 controls the position (the x-coordinate, the y-coordinate, and the z-coordinate) of the template 3. The substrate control unit 107 controls the position of the stage on which the substrate 1 is to be placed.

The application amount control unit 108 controls the discharging unit 109 in accordance with the drop recipe. The discharging unit 109 discharges the droplets 2 onto the substrate 1.

The measuring unit 110 measures the residual film thickness, the pattern size, and the likes by an optical testing method, for example. The measuring unit 110 sends the measurement results to the processing condition generating unit 104.

Next, the operation of the pattern forming device in accordance with this embodiment is described.

First, when the design conditions are input into the design condition input unit 101 by an operator, the residual film thickness calculating unit 102 determines the target value of the residual film thickness to obtain a desired pattern size, with the use of the input design conditions, and the calculation information stored in the calculation information storage unit 103, if necessary.

Based on the calculated target value of the residual film thickness, the processing condition generating unit 104 generates a template distance or a drop recipe. If a template distance is generated, the alignment control unit 105 adjusts the template distance to the generated value. If a drop recipe is generated, the application amount control unit 108 controls the discharging unit 109 to disperse droplets in accordance with the drop recipe.

Thereafter, the light curing organic film 5 is cured through exposure to light, and the cured organic film 6 having the desired residual film thickness is formed as described above. Breakthrough etching is then performed to obtain a desired taper angle. In this manner, a desired pattern size can be obtained.

Next, adjustment of the processing conditions is described in detail.

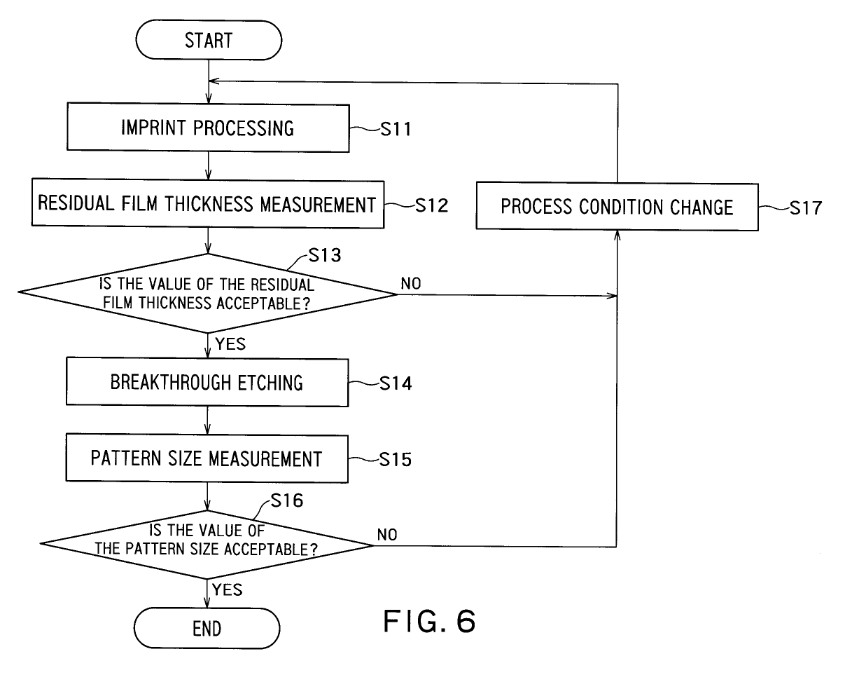

To obtain a desired pattern size, the processing conditions need to be adjusted in practice. Referring now to FIG. 6, the operation flow for the adjustment is described.

1) Among the procedures in accordance with the pattern forming method of the first embodiment, the procedures up to the curing of the light curing organic film 5 through exposure to light and the detachment of the template 3 are carried out (step S11).

2) The residual film thickness is measured by the measuring unit 110 (step S12).

3) The measured residual film thickness is compared with the target value of the residual film thickness, so as to determine whether the measured residual film thickness is within an allowable range (step S13). If the measured residual film thickness is within the allowable range, the operation moves on to step S14. If not, the operation moves on to step S17.

4) Breakthrough etching is performed to form the openings 10 of a tapered shape or reverse tapered shape (step S14).

5) The width of each opening 10 (the pattern size) is measured (step S15).

6) A check is made to determine whether the measured pattern size satisfies a size specification (step S16). If the measured pattern size satisfies the size specification, the operation to adjust the pattern size comes to an end. If the measured pattern size does not satisfy the size specification, the operation moves on to step S17.

The procedure of step S17 is now described. In this step, if the result of measurement carried out on the residual film thickness or the pattern size is unacceptable, the processing conditions are changed. More specifically, the drop recipe or the template distance is changed.

First, an example case where the drop recipe is changed is described. If the measured residual film thickness is smaller than the target value, or the measured pattern size is greater than the size according to the size specification, the distribution shape of the droplets 2 is enlarged, and the distribution density is made higher, so as to increase the application amount of the organic material. The droplet recipe is changed, so as to increase the volume of each droplet 2. If the measured residual film thickness is greater than the target value, or the measured pattern size is smaller than the size according to the size specification, the distribution shape of the droplets 2 is made smaller, and the distribution density is made lower, so as to reduce the application amount of the organic material. The droplet recipe is changed, so as to reduce the volume of each droplet 2.

An example case where the template distance is changed is now described. If the measured residual film thickness is smaller than the target value, or the measured pattern size is greater than the size according to the size specification, the template distance is made longer. If the measured residual film thickness is greater than the target value, or the measured pattern size is smaller than the size according to the size specification, the template distance is made shorter.

In this manner, the drop recipe or the template distance is changed, based on the result of measurement carried out by the measuring unit 110. After that, the imprint process of step S11 is again performed. By feeding back the measurement result as described above, a desired film thickness and a desired pattern size can be obtained.

Alternatively, the processing conditions may be changed (step S17), based on the result of measurement carried out on the size of a pattern formed by processing a film to be processed, with the resist pattern 9 serving as a mask.

The drop recipe and the template distance may be both changed. For example, when the template distance is made longer (shorter), the drop recipe may be changed so as to increase (reduce) the application amount of the organic material at the same time.

In a case where a semiconductor memory device pattern is formed, the cell region and the peripheral region might have different residual film thicknesses from each other as described in the first embodiment. In such a case, the residual film thicknesses are adjusted, with attention being paid to the cell region that is likely to be affected by the pattern size. Accordingly, the template distance and/or the drop recipe is changed based on the result of measurement carried out on the cell region.

As described above, in accordance with this embodiment, the pattern size can be arbitrarily adjusted by imprint lithography, even though the same template is used. Also, the results of measurement carried out on the pattern size and the likes are fed back so as to change the processing conditions. In this manner, a desired pattern size can be obtained. Thus, the increase in TAT due to reform of the template can be minimized.

Additional advantages and modifications will readily occur to those skilled in the art.

Therefore, the invention in its broader aspects is not limited to the specific details and representative embodiments shown and described herein.

Accordingly, various modifications may be made without departing from the spirit or scope of the general inventive concepts as defined by the appended claims and their equivalents.

What is claimed is:

1. A method for forming a pattern by transferring a pattern formed on a template onto an organic material layer,
the method comprising:
applying an organic material onto a substrate to be processed;
bringing the template having a pattern into contact with the organic material, and maintaining a template distance at a predetermined value, the pattern being formed with a plurality of protrusions and a plurality of grooves, the template distance being the distance between the template and the substrate to be processed;
forming a cured organic film by curing the organic material, the cured organic film being formed with organic film convex portions and organic film concave portions each having a predetermined film thickness, the organic film convex portions and the organic film concave portions corresponding to the grooves and the protrusions, respectively;
detaching the template from the cured organic film; and
forming a resist pattern having openings by performing etching on the organic film concave portions in such a manner as to obtain a predetermined taper angle, each of the organic film concave portions being formed into a tapered shape or a reverse tapered shape, each of the openings having a smaller or greater width than the protrusions and being adjusted to a desired pattern size.

2. The method according to claim 1, wherein the predetermined value of the template distance is a value that is determined based on a result of measurement carried out to measure at least one of a film thickness of the organic film concave portions, the width of the openings, and a size of a semiconductor pattern formed by performing etching on the substrate to be processed, with the resist pattern serving as a mask.

3. The method according to claim 2, wherein, when the template has a plurality of pattern regions with different densities, the predetermined value of the template distance is determined based on the result of the measurement carried out in a pattern region having the highest density among the pattern regions.

4. The method according to claim 2, wherein, when the template has a first region having a memory cell pattern formed therein and a second region having a peripheral circuit pattern formed therein, the predetermined value of the template is determined based on the result of the measurement carried out in the first region.

5. The method according to claim 1, wherein the amount of the organic material applied onto the substrate to be processed is adjusted to a sufficient amount to fill a space between the substrate to be processed and the template, and the plurality of the grooves of the template, in accordance with the predetermined value of the template distance.

6. The method according to claim 1, further comprising
performing etching on the substrate to be processed, with the resist pattern serving as a mask.

7. The method according to claim 1, wherein the etching is performed to form the organic film concave portions into tapered shapes, and the openings having x as a width expressed by the following equation:
x=a−2d·tan(90°−θ)
where a represents the width of the organic film concave portions, d represents the predetermined film thickness of the organic film concave portions, and θ represents the predetermined taper angle.

8. The method according to claim 1, wherein the etching is performed to form the organic film concave portions into reverse tapered shapes, and the openings having x as a width expressed by the following equation:
x=a+2d·tan(90°−θ)
where a represents the width of the organic film concave portions, d represents the predetermined film thickness of the organic film concave portions, and θ represents the predetermined taper angle.

9. The method according to claim 1, wherein the organic material applied onto the substrate to be processed is cured after the organic material fills the plurality of the grooves of the template and filling defects disappear.

10. The method according to claim 9, wherein the predetermined value of the template distance is a value that is determined based on a result of measurement carried out to measure at least one of a film thickness of the organic film concave portions, the width of the openings, and a size of a semiconductor pattern formed by performing etching on the substrate to be processed, with the resist pattern serving as a mask.

11. The method according to claim 10, wherein, when the template has a plurality of pattern regions with different densities, the predetermined value of the template distance is determined based on the result of the measurement carried out in a pattern region having the highest density among the pattern regions.

12. The method according to claim 10, wherein, when the template has a first region having a memory cell pattern formed therein and a second region having a peripheral circuit pattern formed therein, the predetermined value of the template is determined based on the result of the measurement carried out in the first region.

13. The method according to claim 1, wherein the organic material is a light curing organic material, and is cured by application of ultraviolet rays thereto.

14. A pattern forming device comprising:
a design condition input unit that has design conditions input thereinto;
a residual film thickness calculating unit that calculates a target value of a residual film thickness, using the design conditions input into the design condition input unit;
a processing condition generating unit that generates a template distance between a template and a substrate to be processed, and/or a drop recipe defining conditions for applying an organic material onto the substrate to be processed, based on the target value of the residual film thickness;
an alignment control unit that controls a distance between the template and the substrate to be processed, in accordance with the template distance generated by the processing condition generating unit; and
an application amount control unit that controls a discharging unit that discharges the organic material onto the substrate to be processed, in accordance with an amount of the organic material generated by the processing condition generating unit.

15. The pattern forming device according to claim 14, wherein the design conditions include a desired pattern size, a taper angle, and a width of a pattern formed on the template.

16. The pattern forming device according to claim 14, further comprising
a calculation information storage unit that stores calculation information to be used for determining the target value of the residual film thickness from the design conditions,
wherein the residual film thickness calculating unit calculates the target value of the residual film thickness, using the calculation information in addition to the design conditions.

17. The pattern forming device according to claim 16, wherein the calculation information is a database that associates taper angles with design conditions for breakthrough etching to be performed to remove residual film portions.

18. The pattern forming device according to claim 14, further comprising
a measuring unit that measures the residual film thickness and/or a pattern size, and sends the measurement result to the processing condition generating unit,
wherein the processing condition generating unit changes the template distance and/or the drop recipe, based on the measurement result.

19. The pattern forming device according to claim 18, wherein the processing condition generating unit generates an increased value for the template distance when the residual film thickness measured by the measuring unit is smaller than the target value, and generates a reduced value for the template distance when the residual film thickness measured by the measuring unit is greater than the target value.

20. The pattern forming device according to claim 18, wherein the processing condition generating unit changes the drop recipe to increase the application amount of the organic material when the residual film thickness measured by the measuring unit is smaller than the target value, and changes the drop recipe to reduce the application amount of the organic material when the residual film thickness measured by the measuring unit is greater than the target value.
